(19) United States
(12) Patent Application Publication
(10) Pub. No.: US 2010/0078715 A1
(43) Pub. Date: Apr. 1, 2010

(54) LATERAL DMOS TRANSISTOR AND METHOD FOR FABRICATING THE SAME

(76) Inventor: Sang-Yong Lee, Bucheon-si (KR)

Correspondence Address: SHERR & VAUGHN, PLLC, 620 HERNDON PARKWAY, SUITE 320, HERNDON, VA, 20170, US

(21) Appl. No.: 12/568,871

(22) Filed: Sep. 29, 2009

(30) Foreign Application Priority Data
Oct. 1, 2008 (KR) 10-2008-0096626

(51) Int. Cl. H01L 29/78; H01L 21/336

(52) U.S. Cl. 257/330; 438/270; 438/286; 257/343; 438/297; 257/E29.261; 257/E21.419; 257/E21.41

(57) ABSTRACT

A LDMOS transistor and a method for fabricating the same. A LDMOS transistor may include a P-type body region formed over a N-well. A LDMOS transistor may include a source region and a source contact region formed over a P-type body region. A LDMOS transistor may include a drain region spaced a distance from a P-type body region. A LOCOS may be formed over a surface of a N-well between a P-type body region and a drain region. A LDMOS transistor may include a main gate electrode formed over at least a portion of a LOCOS and a N-well. A LDMOS transistor may include a sub-gate electrode formed between a source region and a source contact region. A method for fabricating a LDMOS transistor is described herein.

The present application claims priority under 35 U.S.C. 119 to Korean Patent Application No. 10-2008-0096626 (filed on Oct. 1, 2008) which is hereby incorporated by reference in its entirety.

### BACKGROUND

Embodiments relate to electric devices and methods thereof. Some embodiments relate to semiconductor devices including a Lateral Diffused MOS (LDMOS) transistor, and a method of fabricating the same.

It may be advantageous for a semiconductor device to be operable at a relatively high voltage close to a theoretical breakdown voltage of a semiconductor. An external system which may use a relatively high voltage may be controlled by an integrated circuit. An integrated circuit may require a built-in device to control a relatively high voltage, which may be provided with a structure including a high breakdown voltage. For a drain and/or a source of a transistor having a relatively high voltage applied directly thereto, it may be required that a punch through voltage between a drain, a source and/or a semiconductor substrate, and/or a breakdown voltage between a drain, a source, a well and/or a substrate be higher than a relatively high voltage.

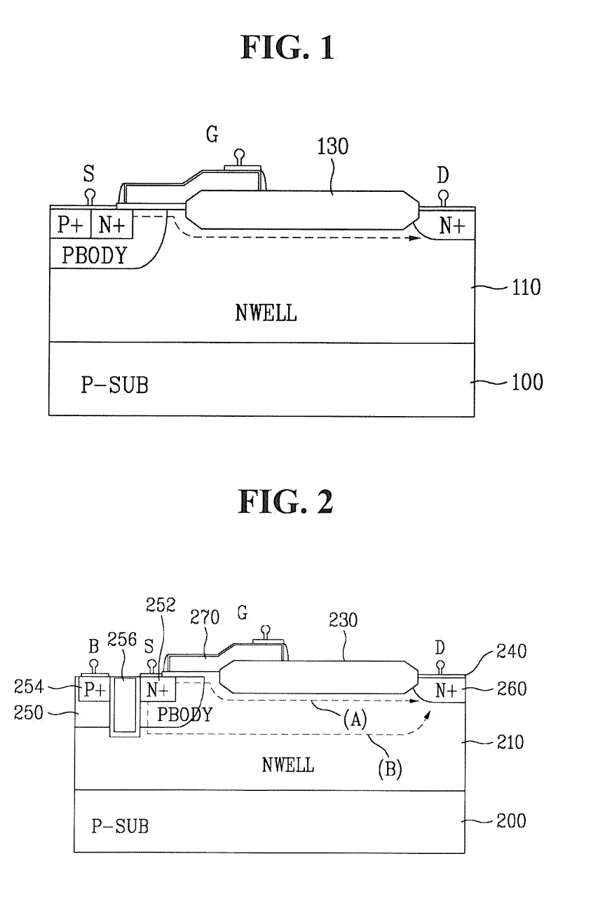

A Lateral Diffused MOS (LDMOS) may be used to address a relatively high voltage for high voltage semiconductor devices. A LDMOS may have a structure suitable for a relatively high voltage since a LDMOS may include a channel region and a drain electrode which may be separated by a drift region and may be controlled by a gate electrode. FIG. 1 illustrates a cross section of a LDMOS transistor:

Referring to FIG. 1, Local Oxidation of Silicon (LOCOS) 130 may be formed at a drift region to moderate an electric field concentrating over a gate edge and/or improve a drain-source breakdown voltage (BVdss). While LOCOS 130 may be effective to improve breakdown voltage (BVdss), LOCOS 130 may not be favorable due to resistance between a drain and a source when compared to a LDMOS, which may not include LOCOS applied thereto. However, if concentration of a drift region is increased to improve resistance between a drain and a source, breakdown voltage (BVdss) may be reduced. Thus, breakdown voltage (BVdss) and resistance between a drain and a source may exhibit a trade-off relation.

Accordingly, there is a need for a device having relatively improved resistance, for example between a drain and a source, while maintaining a level of breakdown voltage (BVdss). There is also a need to manufacture a device which may have relatively improved resistance while maintaining a level of breakdown voltage (BVdss).

### SUMMARY

Embodiments relate to a Lateral Diffused MOS (LDMOS), transistor. Embodiments relate to a method of fabricating a LDMOS transistor. According to embodiments, a LDMOS transistor, and/or a method for fabricating the same, may relatively improve resistance between a drain and a source.

According to embodiments, a LDMOS transistor may include a P-type body region which may be formed over a N-well. In embodiments, a LDMOS transistor may include a source region and/or a source contact region which may be formed over a P-type body region. In embodiments, a LDMOS transistor may include a drain region which may be spaced a distance from a P-type body region. A LOCOS may be formed over a surface of a N-well between a P-type body region and a drain region in accordance with embodiments.

In embodiments, a LDMOS transistor may include a main gate electrode which may be formed over a LOCOS and a N-well. A sub-gate electrode may be formed between a source region and/or a source contact region in accordance with embodiments.

According to embodiments, a method of fabricating a LDMOS transistor may include forming a P-type body region over a N-well. In embodiments, a method of fabricating a LDMOS transistor may include forming a source region and/or a source contact region over a P-type body region. A sub-gate electrode may be formed between a source region and/or a source contact region in accordance with embodiments.

According to embodiments, a method of fabricating a LDMOS transistor may include forming a drain region which may be spaced a distance from a P-type body region. In embodiments, a method of fabricating a LDMOS transistor may include forming a LOCOS over a surface of a N-well between a P-type body region and a drain region. A main gate electrode may be formed over a LOCOS and a N-well in accordance with embodiments.

### DRAWINGS

Example FIG. 1 illustrates a cross section view of a LDMOS transistor.

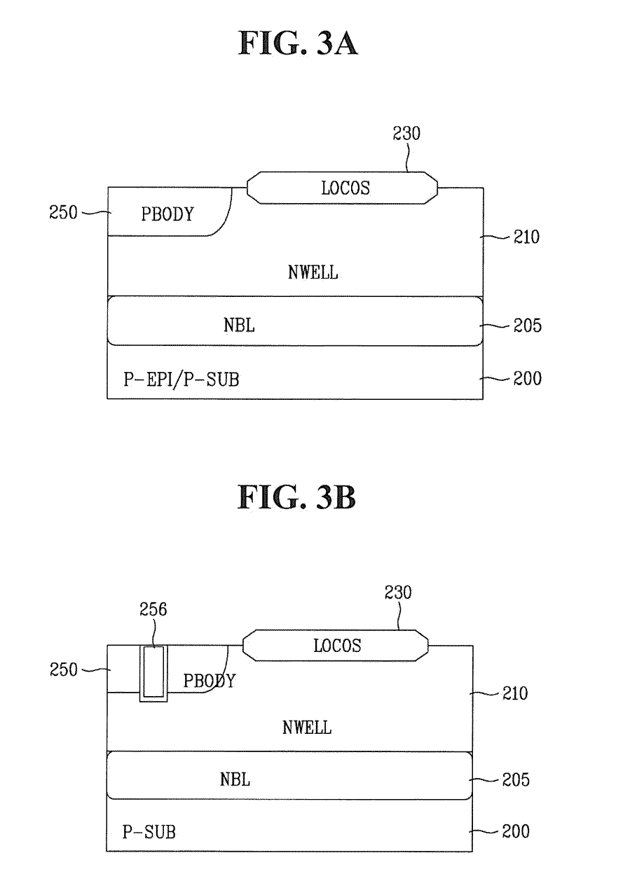

Example FIG. 2 illustrates a cross section view of a LDMOS transistor in accordance with embodiments.

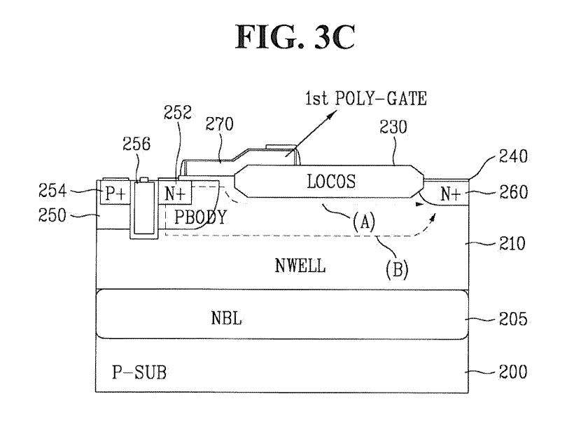

Example FIG. 3A to FIG. 3C illustrates cross section views of a method of fabricating an LDMOS transistor in accordance with embodiments.

### DESCRIPTION

Embodiments relate to a LDMOS transistor. Example FIG. 2 illustrates a cross section view of a LDMOS transistor in accordance with embodiments. Referring to FIG. 2, a LDMOS transistor may include N-well 210. In embodiments, N-well 210 may be formed over a P-type substrate, such as P-type semiconductor substrate 200. In embodiments, LOCOS 230 may be formed over a surface of N-well 210. In embodiments, a drain region 260 may be formed over N-well 210, and may be disposed at one side relative to LOCOS 230.

According to embodiments, a source region, a source contact region and/or a sub-gate electrode may be formed. In embodiments, source region 252, source contact region 254 and/or a sub-gate electrode such as second gate electrode 256 may be formed over another side relative to LOCOS 230, and may be spaced from drain region 260. In embodiments, source region 252 may be doped with N⁺ type impurities. In embodiments, source contact region 254 may be doped with P⁺ type impurities. In embodiments, second gate electrode 256 may have a trench shape and may be formed over P-type body region 250. In embodiments, source region 252 and drain region 260 may be formed over opposing sides relative to LOCOS 230, and may be spaced apart from each other.

According to embodiments, gate insulating film 240 may be formed over a surface of a substrate excluding LOCOS 230. In embodiments, a main gate electrode may be formed such as first gate electrode 270. In embodiments, first gate electrode 270 may be formed over LOCOS 230 between source region 252 and drain region 260. Referring to back FIG. 1, a LDMOS transistor may only have a first current flow path A which may be formed between a source region and a drain region. However, referring back to FIG. 2, by forming a trench between source region 252 and source contact region 254 to form a second gate, a LDMOS transistor in accordance with embodiments may additionally form a second current flow path B.

Referring to FIG. 1, first current flow path A through a channel region formed between a source region and a drain region of a LDMOS transistor including LOCOS may have a loss in view of resistance between a source and a drain since first current flow path A may detour at an underside of LOCOS 230 between a source region and a drain region. However, in accordance with embodiments, a vertical channel may be additionally formed to form an additional current flow path by forming second gate electrode 256 in accordance with embodiments.

According to embodiments, an overall current flow density may be relatively improved owing to additional current flow paths, and resistance between a source and a drain may be improved. In embodiments, current density may be relatively improved without substantially changing the concentration of a drift region. In embodiments, a drop of a source and a drain breakdown voltage (BVdss) which exhibits a trade-off relation with resistance between a drain and a source may not occur.

Embodiments relate to a method of fabricating a LDMOS transistor. Example FIG. 3A to FIG. 3C are cross section views illustrating a method of fabricating a LDMOS transistor in accordance with embodiments. Referring to FIG. 3A, N Buried Layer (NBL) 205 may be formed over a substrate, such as P-type semiconductor substrate 200. In embodiments, N-well 210 may be formed over NBL 210.

According to embodiments, P-type body region 250 and/or LOCOS 230 may be formed over N well 210. In embodiments, a pattern may be formed by depositing a silicon oxide film over a semiconductor substrate having P-type impurities doped therein. In embodiments, a photoresist may be coated over a silicon oxide film, and a photoresist may be subjected to exposure and development, for example using a mask. In embodiments, impurities may be injected into a semiconductor substrate to form a first ion injection region and the photoresist may be removed.

According to embodiments, a photoresist may be coated over the silicon oxide film again, and may be subjected to exposure and development with a mask to form a pattern. In embodiments, a second ion injection region may be formed by injecting impurities into a semiconductor substrate, and the photoresist may be removed. In embodiments, heat treatment may be performed and a silicon nitride film may be deposited thereover.

According to embodiments, a photoresist may be coated over a silicon nitride film, and may be subjected to exposure and development with a mask to form a pattern. In embodiments, a region of a silicon nitride film may be etched using a photoresist pattern as a mask, and the photoresist may be removed in accordance with embodiments.

According to embodiments, an oxidation process may be performed to form LOCOS, for example LOCOS 230. In embodiments, oxidation may be applied to an entire portion of a high voltage region. In embodiments, LOCOS 230 may be formed over N-well 210, and may be spaced a distance from P-type body region 250.

Referring to FIG. 3B, a trench may be formed over P-type body region 250. According to embodiments, a trench may be formed over P-type body region 250 to form second gate electrode 256. In embodiments, second gate electrode 256 may be formed by burying oxide over a trench.

Referring to FIG. 3C, impurity ions may be injected into N-well 210. According to embodiments, impurity ions may be injected into N-well 210 to form N⁺ type drain region 260 and/or P-type body region 250. In embodiments, P-type body region 250 may be formed by making selective P-type impurity ion injection, such as born, at a fixed dose using a predetermined ion injection mask. In embodiments, a portion of P-type body region 250 may operate as a channel region of a LDMOS transistor.

According to embodiments, source contact region 254 may be doped with P⁺-type impurities. In embodiments, source region 252 may be doped with N⁺ type impurities. In embodiments, source contact region 254 and/or source region 252 may be formed over P-type body region 250 on opposing sides of second gate electrode 256. In embodiments, first gate electrode 270 may be formed over a substrate, and gate insulating layer 240 may be disposed therebetween.

According to embodiments, bias voltage may be applied to first and second gate electrode 270 and 256, respectively, at the same time. In embodiments, when a bias voltage is applied, a channel region A disposed along an underside of LOCOS 230 from P-type body region 250 and a vertical channel region 13 formed between source region 252 and drain region 260 may be formed following bias voltage, which may be as a result of second gate electrode 256.

According to embodiments, a first current flow path A may be formed at an underside of LOCOS 230 from P-type body region 250, and a second current flow path B may be formed between P-type body region 250 and drain region 260. In comparison to a LDMOS illustrated in FIG. 1, a second current flow path B in accordance with embodiments may be an additional current flow path formed owing to formation of a trench type second gate electrode 256. In embodiments, a dual current flow path may be formed.

According to embodiments, a LDMOS transistor and a method of fabricating the same in accordance with embodiments, may provide at least a dual current flow path. In embodiments, a dual current flow path may improve resistance between a source and a drain. In embodiments, an overall current flow density may be improved by a dual current flow-path. In embodiments, current density may be relatively improved without substantially changing the concentration of a drift region. In embodiments, breakdown voltage (BVdss) may be substantially prevented from dropping, which may be in a trade-off relation with Rdson.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a P-type body region formed over a N-well;
a source region and a source contact region formed over said P-type body region;
a drain region spaced a distance from said P-type body region;
a Local Oxidation of Silicon formed over a surface of the N-well between said P-type body region and said drain region;
a main gate electrode formed over at least a portion of the Local Oxidation of Silicon and the N-well; and
a sub-gate electrode formed between said source region and said source contact region.

2. The apparatus of claim 1, wherein the N-well is formed over a substrate.

3. The apparatus of claim 2, wherein the substrate comprises a P-type semiconductor.

4. The apparatus of claim 1, wherein at least one of said source region and drain region is doped with N⁺-type impurities.

5. The apparatus of claim 1, wherein said source contact region is doped with P⁺-type impurities.

6. The apparatus of claim 1, wherein said sub-gate electrode comprises a trench type gate electrode formed between said source region and said source contact region.

7. The apparatus of claim 6, wherein said trench type gate electrode comprises a oxide buried in a trench.

8. The apparatus of claim 1, comprising a vertical channel region between said source region and said drain region.

9. The apparatus of claim 8, comprising a dual channel including said vertical channel region and a channel region disposed along an underside of the Local Oxidation of Silicon from said P-type body region to said drain region.

10. The apparatus of claim 9, wherein breakdown voltage does not substantially drop when a bias voltage is applied to said main gate electrode and said sub-gate electrode.

11. A method comprising:
forming a P-type body region over a N-well;
forming a source region and a source contact region over said P-type body region;
forming a sub-gate electrode between said source region and said source contact region;
forming a drain region spaced a distance from said P-type body region;
forming a Local Oxidation of Silicon over a surface of the N-well between said P-type body region and said drain region; and
forming a main gate electrode over at least a portion of the Local Oxidation of Silicon and the N-well.

12. The method of claim 11, comprising forming the N-well over a N Buried Layer.

13. The method of claim 11, comprising forming the N-well over a substrate comprising a P-type semiconductor.

14. The method of claim 11, comprising doping at least one of said source region and drain region with N⁺-type impurities.

15. The method of claim 11, comprising doping said source contact region with P⁺-type impurities.

16. The method of claim 11, wherein forming said sub-gate electrode comprises forming a trench between said source region and said source contact region.

17. The method of claim 16, wherein forming said sub-gate electrode comprises burying a oxide over the trench.

18. The method of claim 11, comprising forming a vertical channel region between said source region and said drain region.

19. The method of claim 18, comprising forming a dual channel including said vertical channel region and a channel region disposed along an underside of the Local Oxidation of Silicon from said P-type body region to said drain region.

20. The method of claim 21, comprising applying a bias voltage to said main gate electrode and said sub-gate electrode at the same time, wherein breakdown voltage does not substantially drop.
